(19) United States
(12) Patent Application Publication
(10) Pub. No.: US 2010/0275902 A1
(43) Pub. Date: Nov. 4, 2010

(54) Photovoltaic and thermal energy system

(76) Inventor: Gerald Falbel, Stamford, CT (US)

Correspondence Address: Mark P. Stone;Attorney at Law, 50 Broadway, Hawthorne, NY, 10532, US

(21) Appl. No.: 12/586,943

(22) Filed: Sep. 30, 2009

Related U.S. Application Data
(60) Provisional application No. 61/215,366, filed on May 4, 2009.

(51) Int. Cl. F24J 2/38; H01L 31/00; H01L 31/052; F24J 2/04; F24J 2/00

(52) U.S. Cl. 126/575; 136/259; 136/246; 126/605; 126/634; 126/602; 126/714

(57) ABSTRACT

A combined diurnal tracking, concentrator, photovoltaic plus domestic hot water solar thermal system is mountable on flat roof industrial buildings or multi-unit apartment buildings for diurnal tracking, and on pitched roofs of single family residences. The systems are configured to reduce the number of solar cells required for given power output, and increased generated heat by a concentration of the sun's insolation on the solar cells. The increased heat is drawn off by anti-freeze fluid circulated in an aluminum extrusion attached to the solar cells and concentrator reflectors for the dual purpose of providing domestic hot water or space heating and maintaining the solar cells cool to enhance their efficiency.

The present patent application claims the benefit of provisional application Ser. No. 61/215,366, filed May 4, 2009; pursuant to 35 U.S.C. 119(e).

### BACKGROUND OF THE INVENTION

Known photovoltaic systems generally employ fixed flat plate solar panels mounted at the latitude angle. These systems are inefficient with regard to a cost per watt for photovoltaic systems.

It is an object of the present invention to decrease the cost per watt for photovoltaic systems, as compared to the flat plate panel systems, by reducing the number of solar cells required for a given power output, while drawing off the heat generated by the concentration of the sun's insolation on the solar cells to maintain the solar cells at a relatively cool temperature to enhance the efficiency thereof, and to provide domestic hot water or space heating.

### SUMMARY OF THE INVENTION

A combined diurnal tracking, concentrator, photovoltaic electricity/solar thermal hot water heating system reduces the cost per watt ratio by reducing the number of solar cells employed in the system by concentrating the sun's insolation on the solar cells. This reduction in the number of solar cells required to provide a given power output is achieved by concentrating sunlight on the cells using refractive or reflective optics, and by employing a simple clock motor to track the sun from sunrise to sunset in the diurnal tracking mode. The combined photovoltaic electricity/solar thermal hot water heating systems in accordance with the present invention are mountable on flat roof industrial and multi-family dwellings, and on pitched roofs such as those generally found on single family residences. The increased heat generated by the concentration of the sun's insolation on the reduced number of solar cells is drawn off by an anti-freeze fluid circulated in an aluminum extrusion to which the solar cells and the concentrator reflective or refractive optics are attached. The circulated fluid is used for the dual purpose of providing domestic hot water or space heating to thereby provide additional cost savings resultant from the combined system, and to maintain solar cells cool to enhance the efficient operation thereof. Preferably, the optical components of the photovoltaic system employ plano mirrors as reflective side panels and a cylindrical Fresnel lens formed from a combination of two extruded acrylic half lenses cemented together. Preferably the diurnal tracking system employs a “checkerboard” mounting pattern on a flat roof, which minimizes shading near noontime.

### BRIEF DESCRIPTION OF THE DRAWINGS

FIG. 1 illustrates a cylindrical pyramid optic concentrator made up of faceted flat sections to spread the sun's irradiance evenly on the solar cells, with solar cells and domestic hot water or space heating, in accordance with the present invention;

FIG. 2 illustrates two types of diurnal tracking systems recessed into a south facing pitched roof, schematically illustrating a diurnal tracking recessed system using either a faceted cylindrical optic, or ½ Fresnal lens showing a diurnal clock drive, a connecting strut, and a copper tube for water or space heating;

FIG. 3 illustrates a 34 solar cell string, arranged in a line and connected in series;

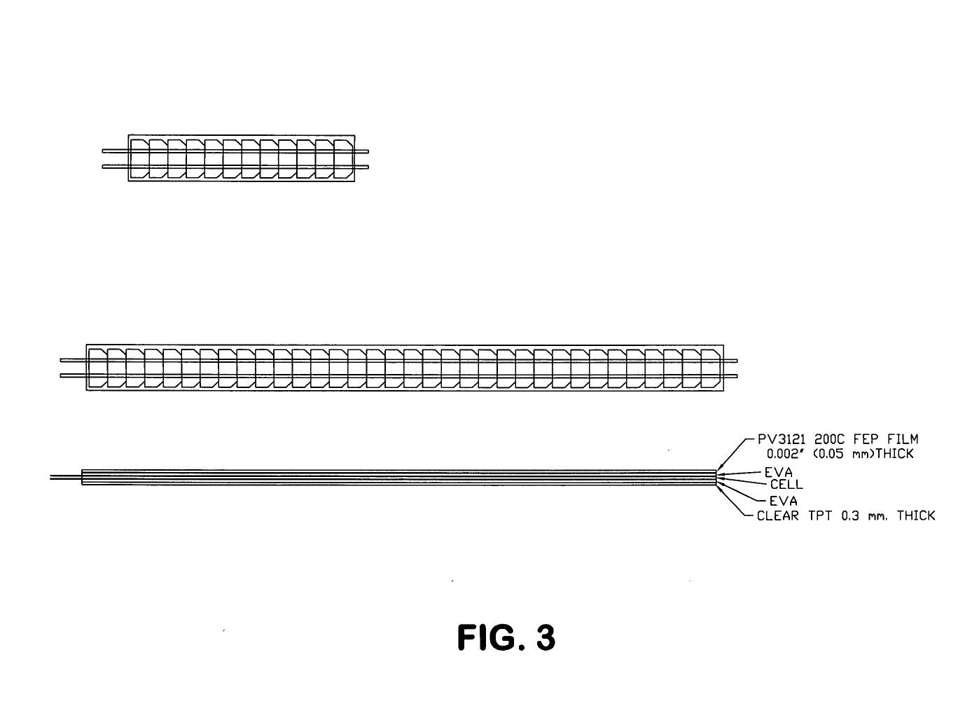

FIG. 4 illustrates sun trajectories at 32° south latitude from a reference;

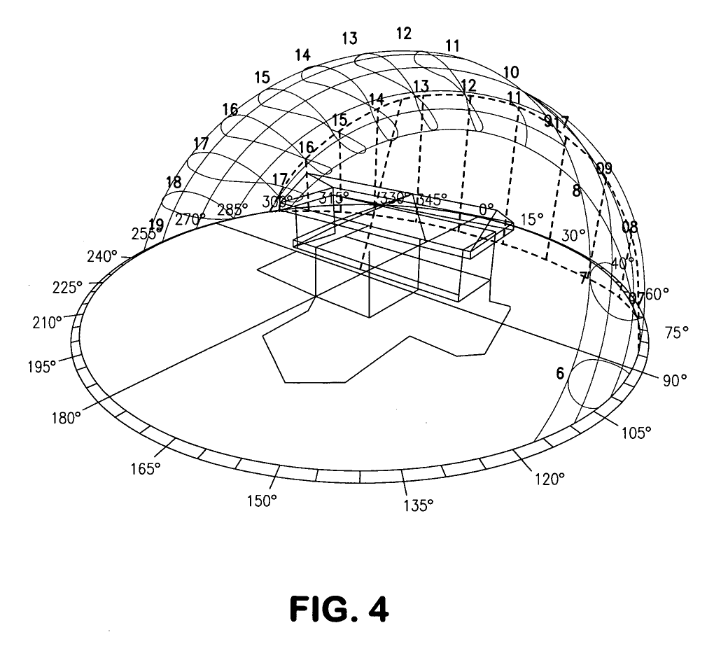

FIG. 5 illustrates sun elevation angular trajectory within concentrator field at 40° north latitude (derived from the FIG. 4 reference);

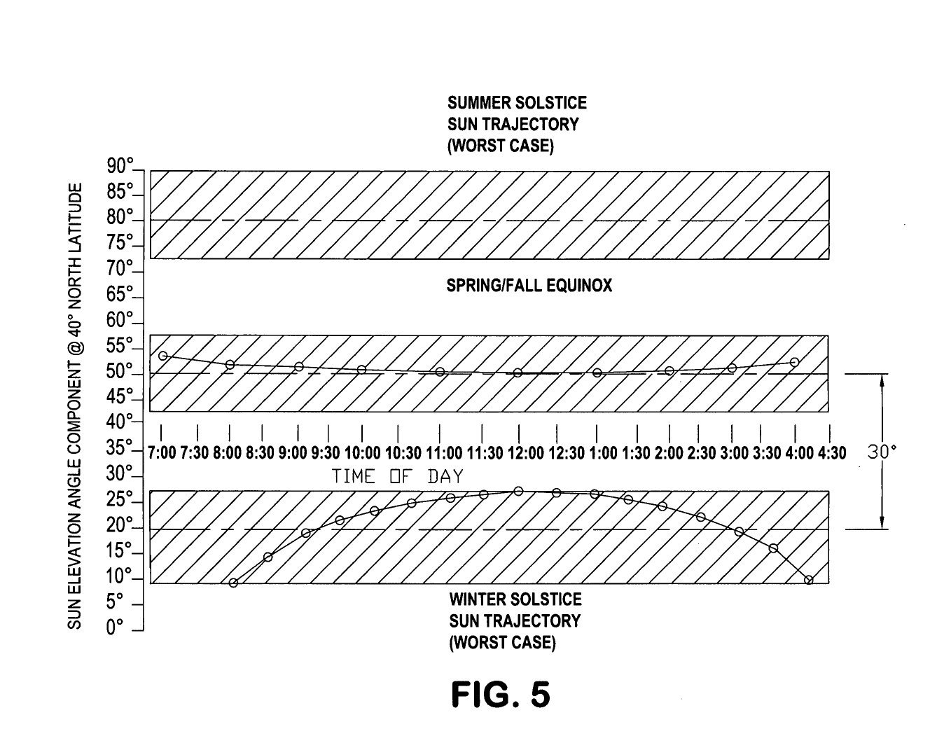

FIG. 6 illustrates an extruded acrylic linear Fresnel lens in combination with piano reflective surfaces;

FIG. 7 illustrates a cylindrical faceted concentrator configuration with a 17 cell string;

FIG. 8 illustrates a flat roof mounting of a Fresnal lens concentrator system; and

FIG. 8A illustrates the diurnal tracking configuration of the system illustrated by FIG. 8.

### DISCUSSION OF THE BEST MODES FOR CARRYING OUT THE INVENTION

A combined diurnal tracking, concentrator, photovoltaic electrical generation system/domestic hot water or space heating solar thermal system is mountable on flat roof industrial buildings; flat roof multi-unit apartment buildings, and pitched roofs of single family residences. The systems in accordance with the present invention may be exclusively diurnal in which the sun is tracked on a daily basis.

The systems in accordance with the present invention achieve a major reduction in the cost-per-watt for photovoltaic systems as compared to flat plate panels by reducing the number of solar cells required for a given power output by almost 3/1 or 6/1. The increased heat generated by a 3/1 or 6.1 concentration of the sun's insolation on the solar cells is drawn off by an anti-freeze fluid circulated in an aluminum extrusion, to which the solar cells and the pyramidal concentrator reflectors are attached. This coolant is used to provide domestic hot water heating, thus providing additional cost savings for the user as well as making the solar cells more efficient, by keeping them cool. The solar array is moved in elevation to coarsely track the sun from winter to summer solstices in the seasonal tracking mode, or pivoted from sunrise to sunset in the diurnal tracking mode using a simple clock motor to track the position of the sun, thus eliminating a costly closed loop solar tracking system. This provides the additional advantage of achieving ideal near normal incidence of sunlight in one axis on the system throughout the year, as compared to fixed flat plate solar panels mounted at the latitude angle. For the diurnal tracking configuration, there is an improvement in energy collected throughout the day by an approximate factor 1.27/1 relative to fixed angle flat plate collectors. The combined electrical energy generation improvement of the solar tracking and the heat removal at the summer solstice equals approximately 40%.

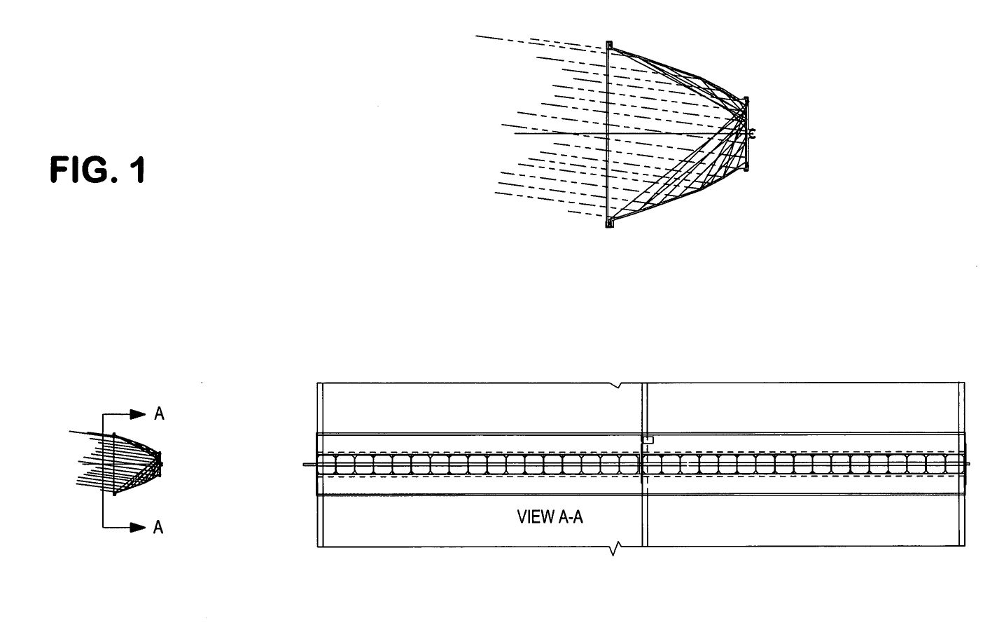

The faceted cylindrical pyramid optic concentrator concept consists of a combined photovoltaic/domestic hot water'or space heating concentrator-collector unit shown in FIG. 1. The insolation incident on the pyramidal concentrator is reflected to commercially available, >17% efficiency solar cells currently available, with a concentration ratio of 3/1. Four cell arrays using standard flat plate panel processes have been fabricated using these cells by SPIRE Inc. In production, 17 cell or 34 cell series strings similar to those currently in production for flat plate panels have been fabricated and will be used.

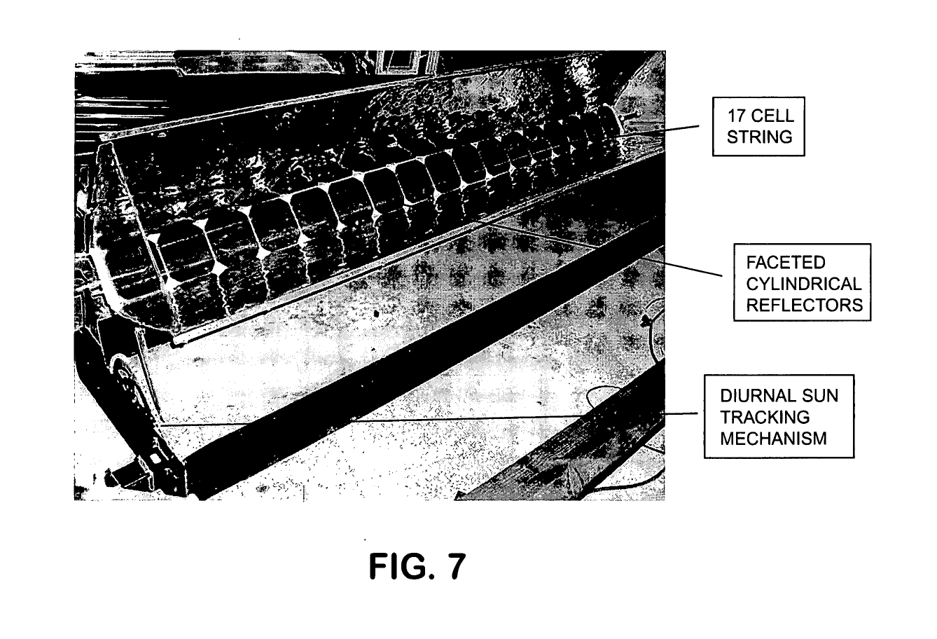

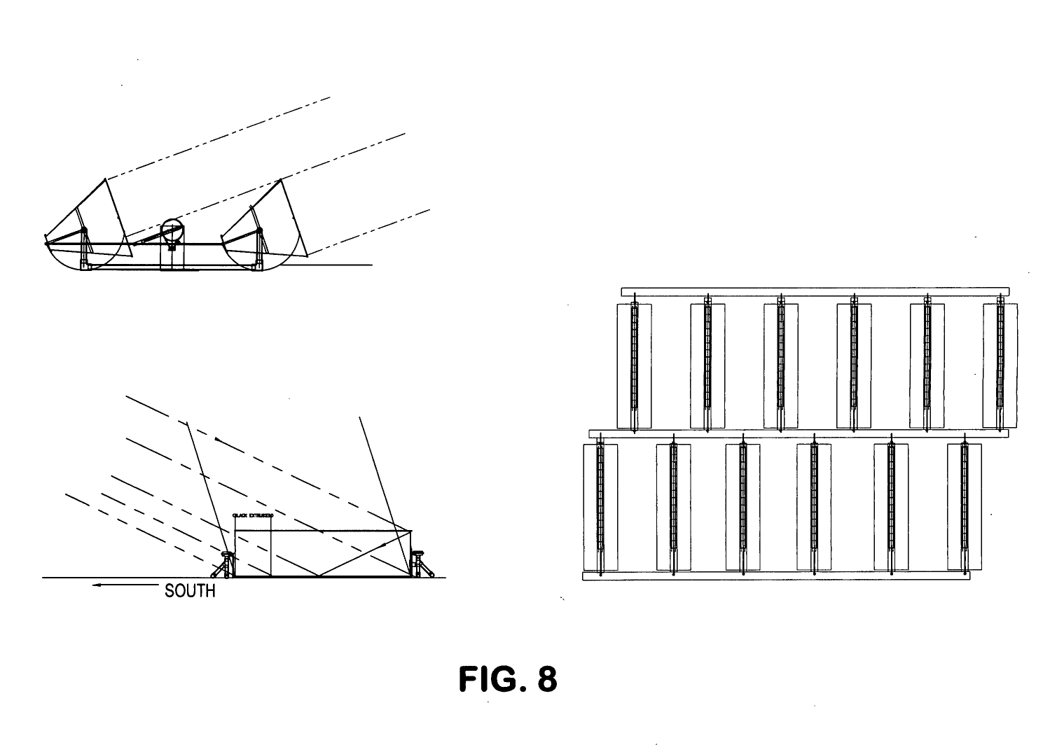

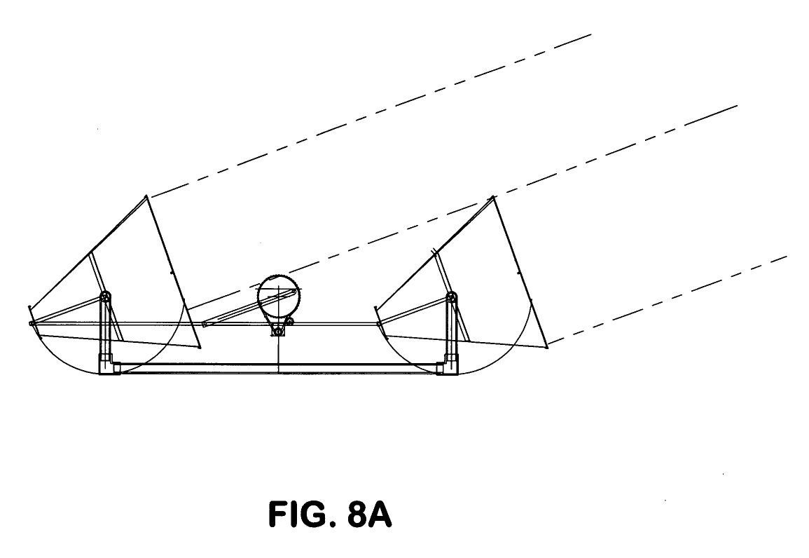

In order to generate 0.68 Kwatt at local noon, six, 17 cell modules using the faceted cylindrical concentrator optics are required. As is shown in FIGS. 1 and 8, these can be arranged in rows, in the north-south direction, on flat roofs or ground installations for industrial applications, thus minimizing wind loads relative to conventional flat plate collectors without domestic water heating. As can be seen in FIG. 1, for hot water applications, the 17 cell arrays are mounted to aluminum extrusions into which copper tubes are snapped. These aluminum extrusions/copper tubing provide additional rigidity for large panels and are used as the frame for mounting multiple modules on roofs through a single axis elevation tracking system. Either anti-freeze (or potable water in non-freezing areas) is pumped through the copper tubes, and the waste heat generated by the solar cells with the concentrated insolation is drawn off by the fluid to heat domestic hot water or provide domestic space heating. It is estimated that a 220 electrical watt system will provide enough waste heat to heat water in an 80 gallon tank from 54° F. to 120° F. in one sunny day. This provides a dual function of providing domestic hot water at close to 70% conversion efficiency (achieved by the 6/1 concentrators with mostly optical reflection/transmission losses), while at the same time generating d.c. electricity for use in grid-tied photovoltaic solar systems currently used in residences, or battery-backup co-generation facilities for minimizing peak power usage in industrial applications. In addition to its economic advantages, the removal of heat from the solar cells for hot water heating also advantageously reduces the operating temperature of the solar cells, to improve their efficiency. Typical efficiency losses of silicon cells are 0.5% per ° C. above 26° C. Therefore, in the summer, by cooling the cells to 25° C., such as in heating a swimming pool, this system will provide a 12.5% improved output as compared to conventional uncooled flat plate panels, which can heat up to 50° C. A photograph of an early prototype of a 17 cell faceted cylindrical concentrator version of the proposed system is shown in FIG. 7.

FIGS. 8 and 8A show a proposed typical mounting of the diurnal tracking configuration on a flat roof. As can be seen, there are no roof penetrations for mounting the solar array, thus eliminating possible leaks caused by the mounting of the solar array. The array is held down to the roof in the presence of wind using “sleepers” made up of wood or galvanized steel angles. The arrays are held down to the roof by the greater than 200 pound combined weight of the optical arrays and the counterweight for each pivoted module. Larger north-south dimensions of the roof repetitions of the basic array shown can proportionally increase its power output. Also, by repeating the array in the east or west direction, the power output can also be increased proportionally.

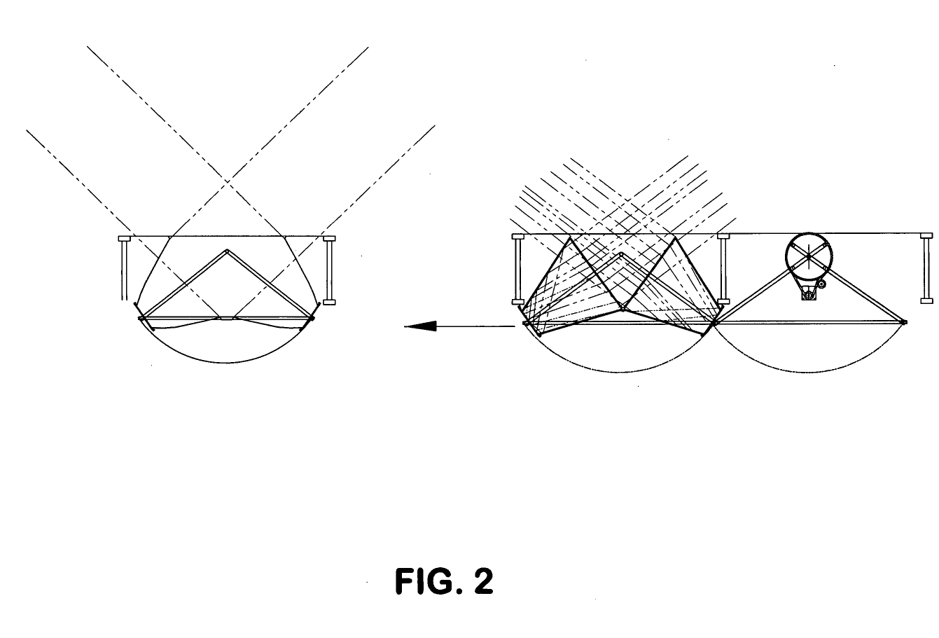

FIG. 2 shows the recessed mounting of the diurnal tracking configuration between the roof rafters on a south facing pitched roof with a slope of the local latitude ±5° for optimum performance, while also improving its aesthetics. In addition, the orientation of the pitched roof to due south can vary by as much as ±15°, without significant losses in diurnal energy generation.

The diurnal tracking mechanism is composed of a 1600 step/revolution stepper motor driving a 75/1 reduction gearbox and a 5.2/1 chain drive system so that an input pulse rate of one pulse per 150 milliseconds closely tracks the diurnal movement of the sun. After sunset, the motor reverses and returns the orientation of the solar array to the time for beginning of solar collection (approximately 7:20 AM local time).

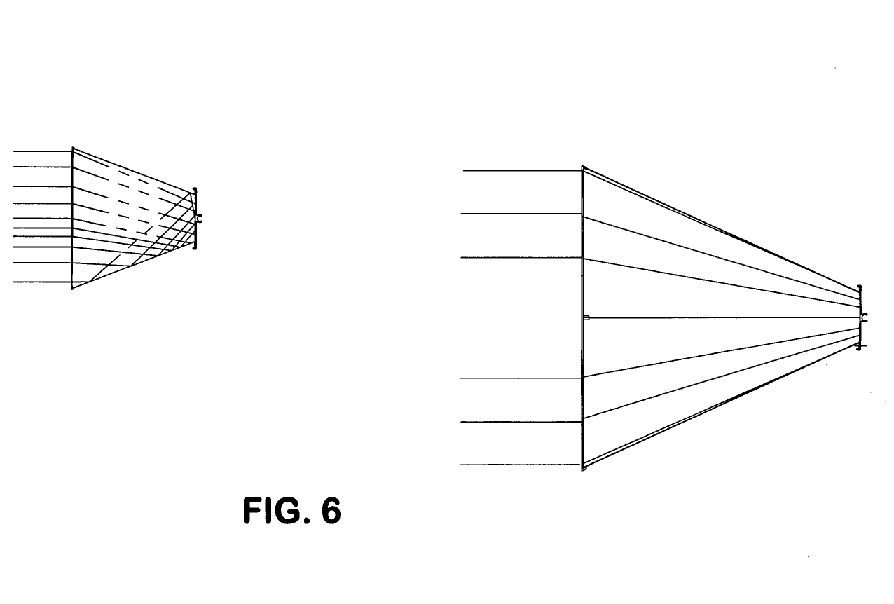

This diurnal tracking configuration, designed for flat roofs, is shown in FIG. 8. In this configuration, the reflective side panels are piano mirrors and a cylindrical Fresnel lens extruded from acrylic material, focuses the sun in a blurred line image caused by chromatic aberrations behind the 34 cell array. As also shown in FIG. 6, the Fresnel lens has dimensions of 30″×108″. This 108″ lens dimension allows the sun to move from winter to summer solstice for the recessed pitched roof configuration shown in FIG. 2, while still passing through the Fresnel lens concentrator and reaching the 86 inch long, 34 cell array under full concentration. Any rays that would miss the array in the East-West direction, due to slight variation in the tracking accuracy and/or lens chromatic aberrations, are still directed to the 34 cell array by the piano side mirrors. The concentration ratio of the Fresnel lens is 30/5=6/1, results in a further reduction of the number of solar cells per output watt by an additional factor of 2/1, as compared to the 3/1 faceted cylindrical concentrator configuration, thereby further reducing the relative cost of this system component, and allowing more efficient cells at a higher cost/cell to be used.

As discussed herein, the preferred optical arrangement for the diurnal tracking system of the present invention employs a Fresnel lens, which is a combination of two extruded acrylic half lenses cemented together, and piano reflective mirrors, for focusing incoming rays of sunlight onto the solar cells for reducing the number of solar cells necessary to produce a desired power output. This configuration is necessary to reduce the cost of the Fresnal lens extrusion die, the cost of which increases exponentially with the width of the extrusion. FIG. 8A illustrates the Fresnel lens piano reflective surface optical arrangement; and FIG. 8A also illustrates diurnal tracking in which the optical concentrator is pivoted by the stepper motor clock drive discussed earlier, between a first position in which incoming rays of sunlight are incident to the front surface thereof at sunrise (e.g., 7:20 AM) to a second position in which incoming rays of sunlight are incident to the front surface at sunset (e.g., 4:40 PM), the concentrator being pivoted throughout the course of the daytime hours to track the position of the sun. FIG. 8A also illustrates tubing coupled to the photovoltaic system for the flow of fluid to remove heat from the solar cells, and to also provide hot water or space heating. FIG. 6 illustrates the Fresnel lens employed as the concentrator for the photovoltaic system, illustrating Fresnel facets extruded on the inside surface of the lens. FIG. 8 also illustrates the aluminum extrusion on which the solar cells are mounted, and into which the tubing for the fluid coolant is connected. As is shown in FIG. 8, preferably, the optical elements are mounted on a flat roof in a “checkerboard” pattern to minimize shading near noon.

FIG. 2 illustrates a configuration of this system for diurnal tracking for south facing pitched roofs. The pivot axis for these collectors are mounted near the window to capture sun for a maximum time period of 7:30 A.M. to 4:30 P.M. with full output and partial output outside this hourly range. The advantage of this approach for the faceted cylindrical reflective configuration is that separate windows on the collectors are not needed.

In summary, the following advantages are applicable to the systems of the present invention:
1. The system uses highly efficiency silicon solar cells currently in production, thus requiring a smaller number of cells for a given power output, thereby reducing solar panel area.
2. The concentrator reduces the number of cells required for a given wattage by a factor of over 2.5/1, or 5/1, thus reducing the highest cost item in a photovoltaic solar panel by at least these ratios.
3. By mounting the encapsulated cells directly to the aluminum extrusion using thermally conducting paste or thermal conducting interface sheets, and not permanently bonding them to the cover glass as is prevalent in flat plate collectors, solar systems can be economically upgraded with more efficient solar cells as they become available, an advantage which is impossible with flat plate solar panels.
4. The high elevation angle of the plane of the window or Fresnal lens at the beginning and/or end of the diurnal tracking day allows any snow buildup to slide off, thereby eliminating the zero energy collection applicable to snow covered fixed flat plate solar panels.
5. The waste heat generated by the solar cells is collected by a solar thermal aluminum substrate containing copper tubes, which provides domestic hot water heating at close to 70% efficiency, while removing excess heat from the solar cells to increase the efficiency of operation thereof, thus providing additional economic justification and reducing the overall payback period.
6. The hot water or space heating extrusions “pay their way” by providing housing rigidity normally provided by the extra cost aluminum housings of flat plate panels.

Experimentation has identified a potential limitation in obtaining the required current output from conventional solar cells as a result of limitations in the conductivity of the ribbon wire used to route the current generated in the cells out to the collector terminals. Modifications to the construction of standard cells used for non-concentrating cells in flat plate collectors can mitigate the limitations. More specifically, use of thicker and wider ribbons and more “fingers” in the solar cell will reduce the combined cell and ribbon resistance by a factor of approximately 10/1. A preferred method of solving this high current problem is to use standard 125 mm.×125 mm. solar cells cut in half to 62.5 mm×125. mm, arranged in strings as shown in FIG. 1. This arrangement doubles the voltage per each 84″ string, and halves the current, while maintaining the same power output, thereby easing the requirements for reducing the resistance of the conducting ribbons. There are additional considerations in making the ribbon wider since for wider ribbon, some sunlight is prevented from reaching the cell, thereby reducing the quantity of electrical energy generated by the solar cell. Accordingly, a tradeoff is necessary in which optimum combination of ribbon with number of ribbons per cell, ribbon thickness, and “finger spacing” maximize the output power of the cell string. This tradeoff is eased by using www.1366tech.com “corrugated” reflective ribbon, manufactured by Ulbrich, Inc., which directs the reflected solar irradiance back onto the solar cell, thereby compensating for the shadow effect and allowing the use of a wider ribbon to reduce electrical resistance and increase electrical conductivity.

### Performance and Cost/Watt

The expected solar power collected by each 17 cells module shown in FIG. 8A using 17% efficiency cells is calculated in Table I. The manufacturing cost of the modules is summarized in Table II. Calculations of diurnal tracking as exposed to flat plate collectors are indicated in Table III.

TABLE I
SOLAR POWER COLLECTION (6/1
FRESNEL LENS SYSTEM)

| | |
|---|---|
| The total aperture area accepting | 2,494 in² |
| sunlight of one module = | |
| The total area of the 17 cells = | 430 in² |
| The light transmittance of the | 0.85 |
| acrylic Fresnel Lens = | |
| Net concentration ratio considering | (2494/430) × |
| transmittance = | 0.85 = 4.93/1 |
| The net output of the cells without | 2.65 watts |
| concentration: = | (mfg. rating/cell) × |
| | 17 = 45 watts |
| The net output of the cells from the | 45 × 4.93 = |
| pyramid reflections:: = | 221.9 watts |
| TOTAL OUTPUT OF ONE 17 CELL MODULE = | 221.9 watts |

TABLE II
MATERIAL COST PER 17 CELL MODULE
USING CHINESE SOLAR CELLS:

| | |
|---|---|
| Prototype quantity quote for sealed 34 | 120.00 |
| cell strings, = | |
| Cost of extruded acrylic Fresnel lens | 195.00 |
| (500 quantity) = | |
| Cost of aluminized polyester reflective | 90.00 |
| side reflectors = | |
| Cost of aluminum extrusion and copper tube = | 40.00 |
| Cement and thermal conduction compound = | 3.00 |
| TOTAL MATERIAL COST | 448.00 |
| Assembly labor = | 20.00 |
| TOTAL COST PER 240 WATT 34 CELL MODULE = | $468.00 |

TOTAL COST IN $/WATT = $468/221.9 = $2.11/WATT + FREE HOT WATER

### Table III

For flat photovoltaic panels (and solar thermal panels) the solar power absorbed by the panel degrades proportional to the cosine of the angle between the perpendicular to the panel and the angle to the sun. For a diurnal tracking system the solar collector is always perpendicular IN ONE AXIS to the sun line, in the elevation plane, so the cosine multiplier is always 1.0. The intergrated energy for fixed flat plate collectors and a diurnal tracking system in watt-hours is given as follows showing that A diurnal tracking system WHOSE PIVOT AXIS IS MOUNTED AT AN ELEVATION ANGLE OF THE LOCAL LATITUDE, provides 27% more Kilowatt-hours per sunny day as compared to fixed panels:

| FIXED FLAT PLATE COLLECTOR: | | DIURNAL TRACKING SYSTEM: | |
|---|---|---|---|
| | IRRADIANCE ABSORBED | | IRRADIANCE ABSORBED |
| TIME | (AT EQUINOX) | TIME | (AT EQUINOX) |
| 12: NOON | 1,000 WATTS/m² | 12: NOON | 1,000 WATTS/m² |
| 1:00, 11:00 | 966 WATTS/m² | 1:00, 11:00 | 1,000 WATTS/m² |
| 2:00, 10:00 | 866 WATTS/m² | 2:00m 10:00 | 1,000 WATTS/m² |
| 3:00, 9:00 | 707 WATTS/m² | 3:00, 9:00 | 1,000 WATTS/m² |
| 4:00, 8:00 | 500 WATTS/m² | 4:00, 8:00 | 1,000 WATTS/m² |

| | |
|---|---|
| TOTAL: 7.1 KILOWATT-HOURS/m² | TOTAL: 9.0 KILOWATT-HOURS/m² |

1. Photovoltaic electrical generator system including at least one solar cell, and means for moving said at least one solar cell for diurnal tracking of the sun.

2. The system as claimed in claim 1, further including an optical element for concentrating sunlight onto said at least one solar cell.

3. The system as claimed in claim 2, wherein said optical element comprises a Fresnel lens.

4. The system as claimed in claim 3, wherein said optical element includes at least one plano reflective surface.

5. The system as claimed in claim 4, further including a plurality of said solar cells and optical elements arranged in a checkerboard pattern.

6. The system as claimed in claim 1, including means for coupling a pipe to said at least one solar cell for removing heat therefrom by fluid flow through said pipe.

7. The system as claimed in claim 6, including means for supplying heat removed from said at least one solar cell to a water heating system for heating water within a water storage tank or for providing space heating.

8. The system as claimed in claim 1, wherein said means for moving said at least one solar cell for diurnal tracking of the sun includes a clock motor.

9. A combined photovoltaic electrical generator and thermal hot water or space heating system, said system comprising:
at least one solar cell, and means for moving said at least one solar cell for diurnal tracking of the sun;
a pipe having a first end coupled to said at least one solar cell, and a second and coupled to a hot water or space heating system;
wherein fluid flow through said pipe removes heat from said at least one solar cell and supplies said heat to said hot water or space heating system.

10. The system as claimed in claim 9, wherein said means moving said at least one solar cell includes a clock motor for pivoting said at least one solar cell for diurnal tracking of the sun.

11. The system as claimed in claim 9, further including an optical element for concentrating sunlight onto said at least one solar cell.

12. The system as claimed in claim 11, wherein said optical element includes a Fresnel lens and at least one piano reflective surface.

13. The system as claimed in claim 1, wherein a plurality of said solar cells form a string, the ratio of width to length along said string being at least 2/1.

14. A method for generating photovoltaic electrical energy, said method including the steps of:
mounting at least one solar cell to a roof structure; and
moving said at least one solar cell for diurnal tracking of the sun.

15. The method as claimed in claim 14, wherein the step of moving said at least one solar cell includes pivoting said at least one solar cell by a clock motor.

16. The method as claimed in claim 14, including the step of providing an optical element for concentrating sunlight onto said at least one solar cell.

17. The method as claimed in claim 16, further including the steps of providing a plurality of said solar cells and optical elements, and arranging said plurality of said solar cells and said optical elements in a checkerboard pattern.

18. The method as claimed in claim 14, further including the step of causing fluid flow proximate to said at least one solar cell for removing heat from said at least one said solar cell for improving the efficiency thereof.

19. The method as claimed in claim 18, further including the step of providing said heat removed from said at least one solar cell to a thermal hot water or space heating system.

20. The method as claimed in claim 19, wherein the step of providing heat removed from said at least one solar cell to a thermal hot water or space heating system includes providing a pipe having a first end in fluid communication with said at least one solar cell and a second end in fluid communication with the hot water or space heating system.
